(19) United States
(12) Patent Application Publication
(10) Pub. No.: US 2007/0011648 A1
(43) Pub. Date: Jan. 11, 2007

(54) Fast systems and methods for calculating electromagnetic fields near photomasks

(76) Inventor: Daniel S. Abrams, Mountain View, CA (US)

Correspondence Address: WILSON SONSINI GOODRICH & ROSATI, 650 PAGE MILL ROAD, PALO ALTO, CA, 94304-1050, US

(21) Appl. No.: 11/245,714

(22) Filed: Oct. 6, 2005

Related U.S. Application Data
(60) Provisional application No. 60/616,789, filed on Oct. 6, 2004.

(51) Int. Cl. G06F 17/50; G03F 1/00; G21K 5/00

(52) U.S. Cl. 716/21; 430/5; 378/35

(57) ABSTRACT

Photomask patterns are represented using contours defined by mask functions. Given target pattern, contours are optimized such that defined photomask, when used in photolithographic process, prints wafer pattern faithful to target pattern. Optimization utilizes “merit function” for encoding aspects of photolithographic process, preferences relating to resulting pattern (e.g. restriction to rectilinear patterns), robustness against process variations, as well as restrictions imposed relating to practical and economic manufacturability of photomasks. Merit function may approximate electromagnetic field using model of mask pattern as infinitely thin, perfectly conducting pattern. Model may also be used for other lithographic methods, including simulation and verification.

### CROSS-REFERENCE

This application claims the benefit of U.S. Provisional Application No. 60/616,789 filed on Oct. 6, 2004, which is incorporated herein by reference in its entirety.

### FIELD OF INVENTION

Field relates to masks, also known as photomasks, used in photolithography processes and, more particularly, to systems and-methods for calculating the electromagnetic fields near a photomask.

### DESCRIPTION OF RELATED ART

Lithographic techniques are used to define patterns, geometries, features, shapes, et al (“patterns”) onto an integrated circuit die or semiconductor wafer or chips where the patterns are typically defined by a set of contours, lines, boundaries, edges, curves, et al (“contours”), which generally surround, enclose, and/or define the boundary of the various regions which constitute a pattern.

Demand for increased density of features on dies and wafers has resulted in the design of circuits with decreasing minimum dimensions. However, due to the wave nature of light, as dimensions approach sizes comparable to the wavelength of the light used in the photolithography process, the resulting wafer patterns deviate from the corresponding photomask patterns and are accompanied by unwanted distortions and artifacts.

As feature sizes on semiconductors shrink, the corresponding mask features are also becoming smaller. Sub-resolution features (such as serifs, hammerheads, and/or scattering bars) exasperate the problem. Typical dimensions of patterns on modern photomasks are now often on the same order or smaller than the wavelength.

Lithography simulation is a critical technology for a variety of purposes, including modern model-based optical proximity correction and mask pattern verification. In such simulations, it may be important to understand the electromagnetics of the photomask. Often, what is known as the Kirchoff approximation (or Kirchoff model) is used. According to this approach, the field behind chrome is considered to have zero amplitude. The field behind glass is considered to have 100% of the incident amplitude. In the case of phase shifting masks, the phase amplitude are as determined by the transmission and phase shift chosen. Although the Kirchoff model is reasonably accurate for large features, the approximation is much less accurate as the mask features become comparable to the wavelength of light.

Another alternative is to solve the full, three dimensional Maxwell equations. Unfortunately, such methods are typically considered too slow to be used on a full reticle scale.

### SUMMARY OF THE INVENTION

Aspects of the present invention may provide systems and methods for approximating the electromagnetic field in the vicinity of a photomask in a rapid manner for purposes of photomask optimization or photolithographic simulation or verification.

Aspects may provide for a photomask pattern to be iteratively modified based, at least in part, on a merit function. The merit function or its gradient may be determined iteratively.

An approximate electromagnetic field may be determined as part of the merit function. In order to improve efficiency of the iteration, the chrome portions of the photomask pattern may be considered to be a 2-dimensional surface. Accordingly, factors relating to thickness may be eliminated in some embodiments. Aspects may also provide for treating the chrome as perfectly conducting, A method may be used to solve Maxwell's equations or a scalar wave equation using these simplifications -for each iteration.

Aspects may provide for initial photomask patterns to be provided in a hierarchical polygon representation, such as GDSII or Oasis, converting the photomask pattern into a pixel based representation, and then calculating a pixel based representation of the electromagnetic field.

Aspects may provide for a photomask pattern to be divided into blocks for processing. For example, a polygon representation may be divided into blocks. For example, a block size of 1 micron by 1 micron up to 10 microns by 10 microns or more may be used, or any range subsumed therein, although this may be varied depending upon the size of repetitive structures or other design features in the pattern. Aspects may provide for overlapping halo regions to be included in the blocks. For example, the halo regions may be determined based on the wavelength of light used for photolithography, such as 193 nm wavelength or other wavelength light. For example, the halo region may provide for an overlap in each direction on the order of a few wavelengths. In some embodiments, the overlap in each direction may be within the range of 0.5 to 2 microns or any range subsumed therein. In some embodiments, the distance for the halo region may be in the range of 5% to 10% of the width or height of the block or any range subsumed therein. The foregoing are examples and other ranges may be used in other embodiments. In example embodiments, a photomask pattern may have more than a million, or even more than ten million gates, and may be divided into more than a million blocks.

Aspects may provide for blocks to be processed using any of the methods described above. In some embodiments, blocks may be processed in parallel using multiple processors, blades or accelerator cards. Aspects may provide for the blocks to be combined after processing to provide an electromagnetic field representation for an entire layer of a semiconductor device or other workpiece. These aspects may provide for efficient full chip calculation of an electromagnetic field.

Aspects may provide a computer readable medium with instructions for any of the methods or method steps described above.

Aspects may provide a computer system with a processor for executing instructions for any of the methods or method steps described. In some embodiments, the computer system may include one or more of a processor, accelerator board, memory, storage and a network interface. Aspects may provide for a system with a plurality of computer systems, server blades, processors or accelerators to process all or portions of a photomask pattern in parallel or in blocks as described above, which may include overlapping halo regions. Aspects may provide for an initial computer system or processor to divide a photomask pattern or design file into blocks as described above for parallel processing and to combine the processed blocks to generate an electromagnetic field representation for an entire layer of a semiconductor device or other workpiece.

It is understood that each of the above aspects of the invention may be used alone or in any combination with one or more of the other aspects of the invention. The above aspects are examples only and are not intended to limit the description or claims set forth below.

### BRIEF DESCRIPTION OF THE DRAWINGS

FIG. 1 is a flow chart of a method according to an example embodiment.

FIG. 2 is a diagram illustrating a halo around a block of a photomask pattern according to an embodiment of the present invention.

FIG. 3 is an example computer system according to an embodiment of the present present invention.

FIG. 4 is an example networked computer system according to an embodiment of the present invention.

### DETAILED DESCRIPTION

In order to calculate a representation of an electromagnetic field, we begin with a description of the pattern on the photomask. A function ψ(x, y) may represent an example photomask pattern by defining the contours which enclose the regions in photomask pattern. ψ(x, y) can be a function which defines the contours implicitly in the sense that a two dimensional function is used to describe a set of contours. Frequently, the function ψ(x, y) is thought of as a real-valued function that defines the contour according to the value of the function along the contour. For example, in one embodiment the mask function ψ(x, y) has the property that ψ(x, y)

1. ψ(x, y)=0 everywhere along the boundary of a region;

2. ψ/(x, y)>0 “inside” a region (for example, those regions corresponding to the chrome portions of the mask);

3. ψ(x, y)<0, or is negative “outside” a region (for example, those regions corresponding to the clear quartz portions of the mask).

In this case, the contours are defined by the “level-set”, i.e. those values in the (x,y) plane such that ψ(x, y)=0. We may also use an area based representation, and in some embodiments, a pixel based representation.

In other embodiments, a variety of functional representation of the photomask, other than that described above, can be used to represent a photomask. We call a two dimensional function that defines the photomask contours a photomask function or mask function. For example, an example embodiment of a mask function would be obtained by assigning negative values to the function values at points on the inside of enclosed regions and assigning positive values to the points on the outside of enclosed regions. Alternatively, one could use the value ψ(x, y)=0 to describe chrome regions ψ(x, y)=1 to describe glass regions, and intermediate values could be used to describe the fraction of a given pixel area which is covered by glass. Yet another alternative would be to choose a level-set other than the zero level-set to specify contours, or to have the function value that represents the location of the contours vary across the photomask, possibly according to another function that defines the values which indicates the location of contours. Still another embodiment would include using binary pixel values, with the value 1 corresponding to chrome, and 0 corresponding to glass, or vice versa.

Although it is convenient to use an area or pixel based representation of the photomask, the use of such representations should not be construed to limit the scope of the invention. For example, the photomask could be described by a set of polygons, or rectangles, or other shape or vector based representation.

In an embodiment, and to facilitate computation, a mask function ψ(x, y) is represented by a discrete set of m function values over a set of m points in the (x, y) plane. In one embodiment, the set of m points comprises a grid spanning an area representing the photomask, in which case they may be thought of as pixels. Alternatively, the set of m points is chosen according to a different arrangement in the area representing the photomask. From this perspective, a mask function ψᵢ(x, y) is determined by the values at the set of m points and consequently can be considered as m dimensional vector.

In a method according to an example embodiment of the present invention, we approximate the chrome layer on a photomask as an infinitely thin layer. In some embodiments, we may also approximate the chrome layer as a perfectly conducting (i.e., perfectly reflecting) layer. In some embodiments, the approximation will be based on the assumption that the chrome layer is of negligible thickness, or, of a thickness that is tiny fraction of the wavelength of the light being used. For example, in some embodiments, the chrome layer may be considered less 10%, less than 5%, less than 2%, less than 1%, less than 0.5%, or less than 0.1% of the wavelength being used, or a range between any of those values.

The approximation thus described has several benefits. One is that the problem is now effectively two dimensional. Consider the photomask as existing on the x-y plane z=0. In a typical embodiment, we have glass above the mask, with some index of reflection n>1. Below, we have air, with index n approximately equal to 1. All of the interesting behavior, however, is a result of the pattern at z=0, in the 2-dimensional plane.

Although the model described is an approximation to reality, it contains much of the essential physics which is missing from the Kirchoff model, is mathematically consistent, and yet is much simpler than the true 3 dimensional problem.

A variety of numerical techniques can be used to determine the electromagnetic field beneath a 2 dimensional surface. For example, Green's function methods or what is known as the Born Approximation.

In one of the simplest embodiments, the electromagnetic field is found in an iterative manner:

$$E ( X ) = \frac{1}{2 π} ∇ \times {\int }_{apertures} ( \hat{n} \times E ) \frac{{ⅇ}^{ⅈ kR}}{R} ⅆ a$$

In the above, the integral is over the tangential component of the E field in the apertures only, that is, the portions of the plane not covered by chrome regions. An initial guess for the electric field is chosen, for example, the Kirchoff solution, or a solution to a similar problem found with a different method. The initial guess is used on the right hand side of the equation to calculate a new value for the E field on the left hand side. The process is then iterated until a reasonably stable solution is reached.

In an iterative application (such as model-based OPC), this approximation can be used in and of itself, or it can be used as an approximate model to calculate changes from a more accurate calculation (such as a fully 3D Maxwell solver), or conversely, as an accurate-model, against which changes based on a Kirchoff approximation can be computed (or, as one of a series of models of increasing accuracy).

In the above discussion, we described a solution of the full Maxwell equations under the physical approximation postulated. However, in some embodiments, the same physical model could be used in a solution for a scalar wave equation as well.

In the above discussion, we described a chrome and glass mask. In photolithography, it is sometimes of interest to solve for an attenuated or alternating phase shift mask. The above methods can be easily modified, by merely solving for the chrome and glass case, and then modifying the solution by adjusting the phase and transmission approximately. For example, in an alternating phase mask, we multiply the solution in phase shifted regions by −1. In an attenuated mask, we can easily add a small intensity of transmitted phase shifted e field. Other similar approximation schemes can be built upon the basic approximation scheme outlined above.

In some embodiments, an entire photomask may be provided as input, and the electromagnetic field for an entire photomask generated as output. In other embodiments, an entire photomask may be provided as input to some other algorithm or process, which in the course of its computation, would break the photomask into various regions or pieces. Each piece may then be simplified and then may undergo further processing. For example, in an optimization process, a large photomask pattern may be divided into many smaller regions, which are each optimized separately. As part of such an optimization, the methods contained herein may be performed on small pieces of the photomask.

The methods described herein can begin with a set of inputs, among them a mask pattern given in a particular format (“pattern I/O formats”). Such formats may include, for example: Image formats, such as bitmnaps, JPEGs (Joint Photographic Experts Group), or other image formats; Semiconductor industry formats, such as GIF, GDSII, Oasis, OpenAccess; or Proprietary formats, such as an Electronic Design Automation (EDA) layout database.

The pattern itself may be a representation of various types of content, for example (but not limited to): One or more levels of an IC design for a particular IC type; A pattern for a non-IC application (e.g. a MEMS device, or disk drive head, or optical component); A pattern which can be used as part of a larger design, such as a standard cell, or DRAM bit cell, etc.

The method may also accepts as input one or more additional parameters, such as the wavelength of light being used, the type of illumination, and the properties of the photomask.

It is contemplated that the teachings of the present invention can be used to calculate an approximate near-field solution for a photomask pattern, which could then be refined through additional approximation schemes. Conversely, various input parameters (such as the illumination, or properties of the photomask) could be calibrated or adjusted in order to improve the accuracy of the present scheme.

The teachings of the present invention can also be employed using a variety of possible input patterns for a variety of possible purposes, including (for example, but not limited to) memory applications (such as DRAM, SRAM, PROM, EPROM, Flash, EEPROM, etc.), microperipheral applications (such as systems support, communication, GPUs, mass storage, voice, etc.), microprocessor applications, digital signal processor (“DSP”) applications, digital bipolar logic applications (general purpose, programmable logic, application specific integrated circuits (“ASICs”), display drivers, bipolar memory, etc.), analog applications, or other non-IC related applications (like MEMS, optical devices, etc.).

In example embodiments, the present invention is applied to a variety of purposes, for example: Various IC applications (DRAM, SRAM, microprocessors, etc.); Various IC technologies (CMOS, MOSFET, copper, GaAs, etc.); Various lithographic processes (double mask, CMP, resist types, damascene, etc.); Various wavelengths (248 nm, 193 nm, etc.); or Various masking technologies (chrome on glass, PSM, CPL, Att-PSM, etc.) resulting from various mask writing technologies (ebeam, laser, raster-scan, shaped-beam, etc.).

Quite generally, the present invention may be applied to any semiconducting manufacturing process, or other process involving lithography.

The methods described herein may be used as part of another algorithm, for example, a model based optical proximity correction algorithm, in which the photolithography process is simulated based on a given mask pattern. In such algorithms, it is typical to simulate the pattern printed from a given mask, the simulated wafer pattern is compared with the intended target pattern, and then adjustments are made in the mask pattern in order to compensate for distortions in the lithography process. The above steps are generally repeated in an iterative manner. Alternatively, other methods may, be used to solve the inverse problem in order to find the optimal photomask.

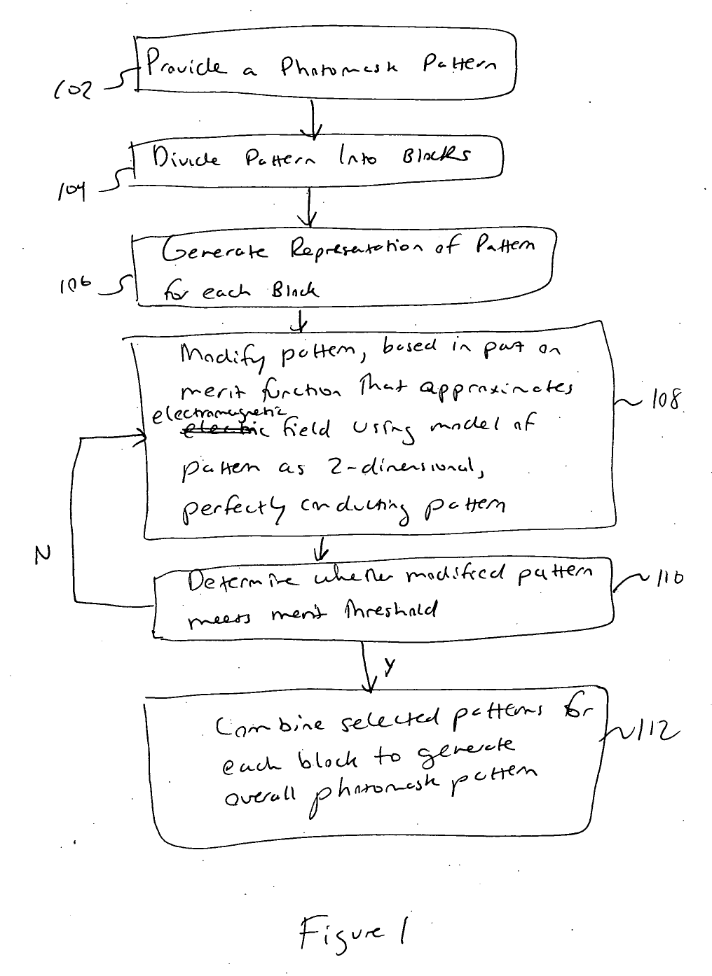

FIG. 1 is a flow chart illustrating an example method according to an embodiment of the present invention. As shown t 102. a photomask pattern is provided. The photomask pattern is then divided into blocks as shown at 104. A representation is generated for the pattern in each block at 106. The representation may be functional (e.g., a level set or distance function), pixel based, polygon based or some other format. At 108 the pattern is modified based, at least in part, on a merit function. The merit function determines electromagnetic field using a simplified model of the pattern as an 2-dimensional, infinitely thin layer. The pattern may also be modeled as perfectly conducting. At 110, the modified pattern is evaluated against a merit threshold or some other threshold (e.g., number of iterations) to determine whether to stop iterating. Once iteration is complete, the optimized patterns for the blocks may be combined as shown at 112. The above method may be implemented in software and the representations of the photomask may be stored and modified in computer memory as described further below. The resulting mask pattern may be used to manufacture a photomask. The above method is an example only and embodiments of the present invention may be used for other photolithographic methods that use the electromagnetic field of a mask pattern, including photolithographic simulation and verification.

In some embodiments of the present invention, lithography simulation may be used to verify that a given photomask correctly prints a wafer pattern as intended. In these circumstances, it may be advantageous to have a more accurate model of the electromagnetic field than that obtained from the Kirchoff approximation.

In another embodiment, we exploit the fact that repeated patterns exist in an IC circuit design, some of which patterns may themselves be composed of repeating patterns and so on in a hierarchy, to first optimize a photomask segment or region on the bottom of the hierarchy (that is, the smallest pieces often referred to as “standard cells”). Combinations of these solutions can then be used as the initial guesses for solutions (in step 903) to larger pieces, and combinations of these larger solutions can then be used as the initial guesses for even larger pieces, etc. Applying the teachings of the present invention in a hierarchy process may in some cases allow for very fast convergence, especially when local criteria are used to determine convergence.

An example embodiment of the present invention the granularity or placement of the grid of points on the photomask is adjusted in a time-dependent fashion as the algorithm approaches convergence. By performing the initial iterations on a larger grid, and increasing the number of grid points with time as greater accuracy is desired, a solution is obtained more quickly. Other such “multi-grid” techniques will be apparent to those skilled in the art. Another possibility is using an adaptive mesh technique, whereby the grid size varies locally.

Sub-Grid Resolution

In an example embodiment, the mask function may have the following useful property: when such a function is stored in a computer using a pixelized representation, that is, as a matrix of values sampled from a grid in the (x,y) plane, the pixelized representation can specify the precise location of the contours at a resolution substantially smaller than the pixel size. For example, if the pixels are stored in a computer using 32-bit floating point values, rather than the pixel size. This is an example only and the value of a mask function may be specified with other resolutions as well, such as 64 bit values, 8 bit values or other values which can be different that the resolution provided by the pixels.

When the mask function is represented by a discrete set of values, most commonly (but not necessarily) arranged in a grid of pixels, it is often the case that the contour defining the boundaries between the regions of the photomask pattern does not fall exactly on a pixel boundary. For example, if the mask function is chosen as a level-set function with the zero level-set defining the boundary, than the value ψ0 (x, y)=0 may not occur for any discrete x,y sampled by a particular pixel. In such a representation, one possibly beneficial approach is to initialize the pixel values such that they indicate the position of the boundary with sub-pixel resolution. For example, if the mask function is a distance function, then the value of the pixels near the contour can be set to the signed distance to the contour corresponding to the initial pattern.

The above approach can also be applied when using multi-resolution or multi-grid techniques, or in an adaptive mesh approach, or in a local level set approach, or virtually any other approach that represents a continuous mask function with a discrete set of values, even if the mask function is not represented by a simple pixel map. Accordingly, alternative embodiments (such as alternative mask functions and means of interpreting and representing mask functions) would also fall under the present invention.

A pattern I/O format may be used to read in the photomask. In one embodiment of the invention, the pattern I/O format used may be based on what we call a vector or polygon type description, by which we mean that the description of the pattern contains the start and end points of various lines, or the vertices of polygons, or other means of describing the shapes of the pattern that are not inherently pixel-based. GDSII and Oasis would be examples of such polygon-type descriptions. It is an aspect of an example embodiment of the invention that such patterns upon input may be converted from polygon-type representations into area or pixel based representations. Such representations might include a representation based on binary pixels, or possibly a mask function representation as described previously, which might include, for example, a distance function representation. Such conversions between formats may take place at a resolution finer than the pixel size or grid size of the area based representation, if it uses pixels or values sampled on a grid.

Parallel System

It is often the case that a photomask will be quite large, in the sense of having a large number of contours. Alternatively, in a pixelized representation, such a photomask would consist of a large number of pixels. Computing the electromagnetic field for an entire photomask at one time on a single CPU may be computationally demanding. In such situations, it may be beneficial to divide the pattern into separate regions, and process each region on a separate compute node in a cluster of machines.

There are several ways in which such parallelization can be accomplished. In one approach, the plane is partitioned into non-overlapping regions, with each region to be solved on a particular compute node, and each individual node communicates information about the region it is processing and its boundary conditions to those nodes that are processing neighboring regions. An advantage of this method is that a large number of processors can be used simultaneously to process a large area, in such a manner that the solution obtained would be exactly the same as in the case in which all of the work was accomplished on a single node.

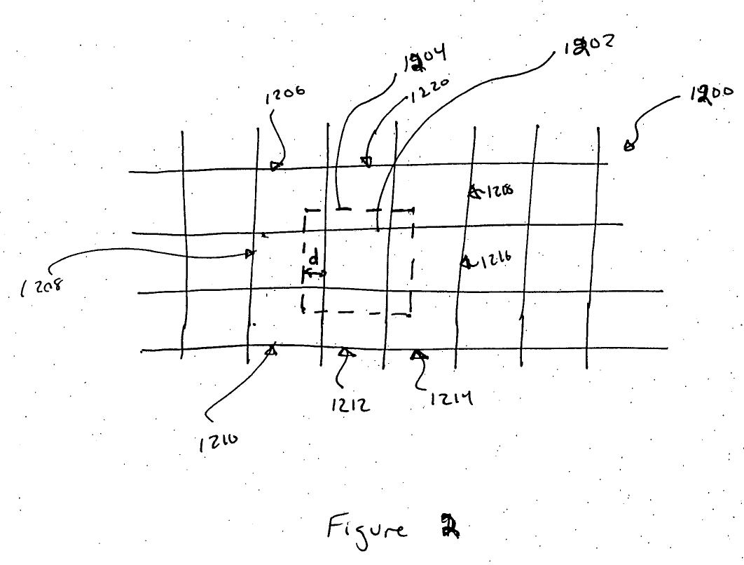

In an alternative approach, the plane is divided into separate non-overlapping regions, but when such regions are processed on individual compute nodes, the machines compute each region along with a halo region of a fixed thickness surrounding the given region. Because the impact of one area of a photomask on another area of the same mask diminishes with distance, the results found in this approach will be almost the same as if the entire mask was processed on a single compute node, as long as the halo thickness is sufficiently large. FIG. 2 illustrates a portion of a photomask pattern divided into an array of blocks 1200, including block 1202. The block 1202 will have a pattern specified for a portion of the integrated circuit or other workpiece. The size of the blocks may depend upon the features of the design, including the size of repetitive structure, boundaries that provide processing efficiency, or other criteria. In some embodiments, a fixed block size may also be specified. For instance, in an example embodiment, the blocks in FIG. 2 may range from 1 micron by 1 micron to 10 microns by 10 microns, or any range subsumed therein. These are examples only and other block sizes may be used. As shown by the dashed line at 1204, a halo may be defined around block 1202. This halo overlaps with adjacent blocks 1206, 1208, 1210, 1212, 1214, 1216 and 1220. The halo extends beyond the block 1204 by a distance d in each direction. The distance may be selected based on process parameters and the level of expected interference from adjacent regions and computational complexity (since the halo increases the size of each region that is be processed). While the size of the halo may vary, in some embodiments, it may range from 0.5 microns to 2 microns or any rang subsumed therein or from 5% to 10% of the width or height of the block or any range subsumed therein. These are examples only and other halo sizes may be used.

An advantage of this method is that each region along with its halo can be processed completely independently of all other regions. In yet another approach, the entire photomask is divided into regions with halos as above, but the computer analyzes such regions in order to find repetition. If a particular region of the mask pattern, halo included, is identical to a similar area in another portion of the mask pattern, then this region need only be processed once, since both instances will yield identical results. Since it often occurs that a single pattern repeats many times throughout a design, using this approach to eliminate repetition can be advantageous. Other approaches to parallelizing the problem are also possible, depending on the computer architecture.

In one embodiment of the invention, the design is provided as one of a set of inputs to a computer system. The design could be sent over a network or it could be provided on tape or on a variety of removable storage media: The computer system would begin by analyzing the design and breaking it into a large number of individual pieces. In one embodiment, the design is stored in a file system, and one or more servers that have access to the file system would perform this step. Alternatively, the file system may be local to one or more of the servers (such as a local hard drive). The cutting up of the design could be based upon a variety of criteria, as there are multiple ways of dividing a design into pieces. The pieces may be square, or rectangular, or any other shape. It is usually preferable for the pieces to be non-overlapping (not counting the halos, which if they are included, are overlapping by definition), but it is not necessary for the pieces to be non-over-lapping. In some embodiments, the design may be stored in an intermediate format, different from the original input format. In one embodiment, the design is “flattened” before processing, so that the breaking of the design into pieces does not need to consider hierarchy. In another embodiment, a partition is predetermined to guide the cutting processes, and as the input file is read, polygons are divided into files according to which partition they would fall under. Still other approaches for reading, analyzing, and breaking a design into pieces are possible within the scope of the invention.

Once the design has been broken into multiple pieces, each piece could then be sent to one or more servers designed to process the pieces and solve for the electromagnetic field for each piece. The second set of servers may include the original set of servers, or may be a distinct machine or set of machines. The transmitting of the data could include sending the data over Ethernet, or Myrinet, or Infiniband, or any other method by which two or more computers can exchange information. Alternaively, the separate pieces can be written to a file system which one or more servers can access independently, as a means of transferring data from the original set of machines to the second set of machines. The data describing the individual pieces could be based on a pattern I/O format, or another polygon-type representation, or it could be a pixel or grid based representation, or an area based representation, such as a mask function or bit map. Optionally, additional information could be included, such as process information, for example, the wavelength or numerical aperture. In one embodiment of the invention, the individual pieces include halos so that they can be processed separately. In an alternative embodiment, some pieces may not include halos or may include halos on only some of the edges, and information is shared between pieces, as described previously, in order to address the boundaries for the edges which are not padded by halos. Such an implementation may be used, for example, on a shared memory multi-CPU machine, where information is easily and efficiently transferred between simultaneously running processes.

As it may be advantageous to minimize the amount of processing that needs to be completed, in some embodiments the system may optionally determine if there is repetition among pieces of the design to be processed. One way in which this can be accomplished is to calculate a signature for each piece, and then look for pieces with identical signatures. Another approach is to simply compare the pieces directly. In one embodiment, this repetition analysis is done during the first step, before the pieces are sent to be processed. Alternatively, in the second step, before a server begins to process a piece, it can look to see if an identical piece has been processed previously. Other approaches are also possible and fall within the scope of the invention.. Because the decision as to how the pieces are cut will impact the amount of repetition, in some embodiments it may be desirable to consider possible repetition in the design during the cutting step. For example, if a design is based on cells, the pieces can be chosen to correspond to the individual cells, which are likely to appear in more than one place. Another possibility would be to choose rectangles which correspond to groups of such cells. Still another embodiment would arbitrarily cut the design into strips in one direction, but within each strip, choose rectangular pieces which are aligned with cell boundaries or other elements of the design, in such a way so as to maximize the possibility of finding repetition.

In one embodiment, once all the individual pieces are processed, the results are transferred to a third set of servers, which may be one or more servers and may or may not include one or more servers from the first and second set. Transferring of data can take place by a variety of means, as described previously. The third set of machines may assemble the pieces back together into a complete description of the electromagnetic field beneath the photomask. In an alternative embodiment, the entire electromagnetic field description is never assembled, but rather, information about the electromagnetic field from each piece is used in some other calculation, and the results are assembled. For example, the electromagnetic field may be used as part of a lithography simulation which is in turn used to determine if a given piece of photomask prints an acceptable on wafer image. In that example embodiment, the data collected together from all the nods may only consist of whether or not each piece printed an acceptable image. In a variation of that example embodiment, other information, such as an edge-placement-error histogram, may be assembled.

It is possible that one or more of the steps outlined above could be executed in parallel on one or more machines; for example, as the design is processed, individual pieces could be sent to another machine which would compute the electromagnetic field even while the first machine is still doing other work. Such an approach could be considered a pipe-lined architecture. Similarly, parts of one or more of the steps could be completed on one or more servers while others are working on one or more of the other steps. In some embodiments, all of the steps would be performed on a single machine, or a single multi-processor machine (i.e., a single machine with multiple CPUs).

In the foregoing discussion, the servers described above could be any one of a number of different computing devices. One possibility would be standard blade servers; another possibility would be standard 1 U rack mounted servers, or rack mount servers of various sizes, or another possibility would be a cluster of standard desktop machines or towers. In one embodiment, the processing would take place on a general purpose microprocessors, also called a GPU or CPU. For example, an Intel Pentium or AMD Opteron could be used. In other embodiments, the computing could be done on an FPGA, DSP, or ASIC. In one embodiment, some of the work would be done on a GPU and other parts of the work would be done on another device. For example, the GPU could be used to process polygons, transfer data, read and write files, convert formats, and a variety of general tasks, and an FPGA could be used to perform other steps in the calculation, for example, steps involving mathematical operations on pixels. It is possible that an FPGA or ASIC could be specifically designed for these purposes. One approach would be to use an FPGA, DSP, or ASIC to exploit the parallelization inherent in processing large arrays of pixel values. For example, a server could consist of a standard GPU along with a special accelerator board attached to the server which contains one or more FPGAs, DSPs, or ASICs, along with local on board memory. Pieces of designs could be passed to the GPU for processing, which would perform miscellaneous tasks as described above, and then transfer arrays to the board containing the special purpose processors, which would then perform computations on the pixels. The results could then be transferred back into the main memory of the mother board, allowing the GPU to perform any additional post processing and/or transfer the results back to another server or set of servers. It is also possible that the system could be designed such that the GPU has access to the memory of the accelerator board as well as its own memory, and in some embodiments the GPU might perform operations interspersed with work performed by the FPGAs, DSPs, or ASICs.

Example System Architectures

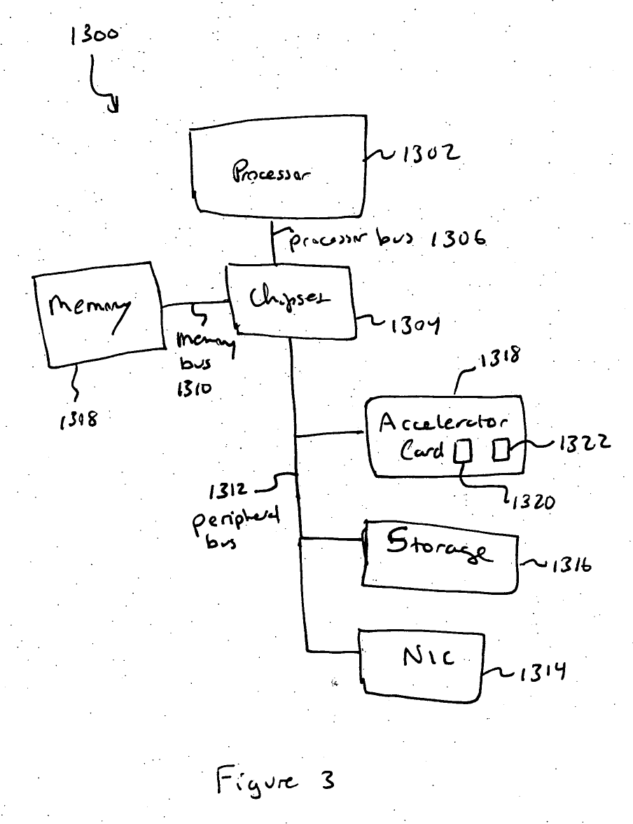

FIG. 3 is a block diagram showing the architecture of an example computer system, generally indicated at 1300, according to an embodiment of the present invention. As shown in the example embodiment of FIG. 3, the computer system may include a processor 1302 for processing instructions, such as a Intel Pentium™ processor, AMD Opteron™ processor or other processor. The processor 1302 is connected to a chipset 1304 by a processor bus 1306. The chipset 1304 is connected to random access memory (RAM) 1308 by a memory bus 1310 and manages access to the RAM 1308 by the processor 1302. The chipset is also connected to a peripheral bus 1312. The peripheral bus may be, for example, PCI, PCI-X, PCI Express or other peripheral bus. In some embodiments, an accelerator card 1318 may be connected to the peripheral bus 1312. The accelerator card 1318 may include ASIC or other hardware for accelerating processing 1320. The accelerator card 1318 may also include on-board memory 1322. The computer system 1300 also includes one or more network interface cards (NICs) 1313 connected to the peripheral bus for providing network interfaces to a network. External storage 1316, such as a disk array or other non-volatile storage, is also connected to peripheral bus 1312.

Software instructions for implementing any of the methods described above may be stored in memory 1308, storage 1316, on board memory 1322 or other computer readable media and may be processed by the processor 1302 or accelerator card 1318. Representations of photomask patterns or blocks or portions of the foregoing and other inputs and outputs may also be stored in memory 1308, storage 1316, on board memory 1322 or other computer readable media and may be processed by the processor 1302 or accelerator card 1318. These items may be stored in data structures or files or in other formats. In some embodiments, as described above, a functional representation of a photomask pattern or portion of a photomask pattern may be stored in an array, where the value of the function at grid points across the area of the pattern are stored in the array. In some embodiments, the processor may process a photomask pattern or portion of a photomask pattern in a polygon representation such as GDSII or Oasis and convert it to a functional representation using a grid or pixelized representation. It may then be provided to on board memory 1322 and processed by the accelerator card 1318. The accelerator card 1318 may include specialized hardware 1320 that efficiently processes pixel arrays.

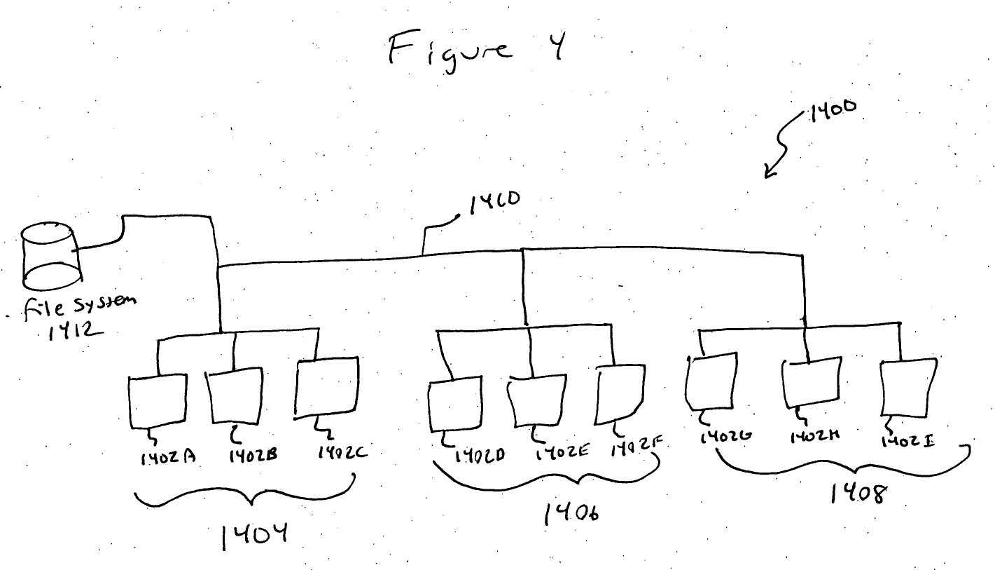

FIG. 4 is a block diagram showing a networked computer system 1400, according to an embodiment of the present invention. In an example embodiment, each of the computers 1402a-i may have the architecture shown in FIG. 3 or other architecture and may be used for multi-processing to efficiently process a large integrated circuit design. The system may have a network file system 1412 (corresponding to external storage 1316 in FIG. 3) that is shared by the computers. It will be understood that other architectures may be used as well for multi-processing as described above, including a computer with multiple processors, a server with multiple blades or other architectures. One of the computers, or a group of computers 1404, may receive a pattern for a layer of an integrated circuit device. This group of computers 1404 may convert the pattern from hierarchical to flat format and divide the target pattern into blocks, which may include halos as described above in connection with FIG. 2.

In an example embodiment, the pattern may be for a complex integrated circuit design with more than 10 million gates. In an example embodiment, the first group of computers may divide this pattern into 1 million or more blocks for processing. The pattern for the blocks generated by computers 1404 may be stored in files in file system 1412 or in data structures in memory and may be accessed by other sets of computers 1406 and 1408 over network 1410. The first set of computers 1404 may assign blocks to queues in file system 1412 to be processed by individual computers 1402d, e and f. In this way, the load can be balanced and a large complex design can be efficiently processed using multi-processing.

A second set of computers 1406 may access the blocks for processing. Each computer 1402d, e and f may be retrieve blocks from its queue and process them. The results for the block may be stored in file system 1412 and accessed by a third set of computers 1408.

The third set of computers 1408 may assemble the blocks to generate the electromagnetic field for the entire mask pattern, or a portion thereof, or may collect data about the mask pattern which is calculated in part by using the electromagnetic field found for each block.

Various elements and steps in the description and example embodiments above may be applied independently or in various combinations. For example, a variety of methods for finding an optimal photomask may be used in combination with aspects described above, including but not limited to the method of Nashold projections, variations of Fienap phase-retrieval algorithms, coherent approximation with deconvolution, local variations, descent searches, linear and nonlinear programming, pixel flipping, quadratic optimization, linear and nonlinear least squares, Gerchberg-Saxton algorithm, simulated annealing, genetic algorithms. For example, the parallel system architecture described previously may be applied to a variety of photomask optimization methods in conjunction with the methods of calculating electromagnetic fields.

Accordingly, while there have been shown and described above various alternative embodiments of systems and methods of operation for the purpose of enabling a person of ordinary skill in the art to make and use the invention, it should be appreciated that the invention is not limited thereto. Accordingly, any modifications, variations or equivalent arrangements within the scope of the attached claims should be considered to be within the scope of the invention. In addition, the foregoing description of the principles of our invention is by way of illustration only and not by way of limitation. For example, although several illustrative embodiments of methodologies in accordance with the principles of our invention have been shown and described, other alternative embodiments are possible and would be clear to one skilled in the art upon an understanding of the principles of our invention. For example, several alternatives have been described for various steps described in this specification. It should be understood that one alternative is not disjoint from another alternative and that combinations of the alternatives may be employed in practicing the subject matter of the claims of this disclosure. Certainly the principles of our invention have utility apart from making photomasks for integrated circuits, some of which we have already mentioned. Accordingly, the scope of our invention is to be limited only by the appended claims.

Foregoing described embodiments of the invention are provided as illustrations and descriptions. They are not intended to limit the invention to precise form described.

In particular, it is contemplated that functional implementation of invention described herein may be implemented equivalently in hardware, software, firmware, and/or other available functional components or building blocks. Other variations and embodiments are possible in light of above teachings, and it is thus intended that the scope of invention not be limited by this Detailed Description, but rather by Claims following.

What is claimed is:

1. A computer readable medium including instructions for:
generating a representation of a photomask pattern;
approximating an electromagnetic field in the vicinity of the photomask pattern using a 2-dimensional model of the photomask pattern.

2. The computer readable medium of claim 1, wherein the model represents the photomask pattern as perfectly conducting.

3. The computer readable medium of claim 1 further comprising instructions for iteratively modifying the representation of the photomask pattern based, at least in part, on the approximation of the electromagnetic field.

4. The computer readable medium of claim 2 further comprising instructions for iteratively modifying the representation of the photomask pattern based, at least in part, on the approximation of the electromagnetic field.

5. The computer readable medium of claim 2 further comprising instructions for dividing the photomask pattern into blocks, wherein approximating an electromagnetic field in the vicinity of the photomask pattern using the 2-dimensional model of the photomask pattern further comprises applying the model separately to each block.

6. The computer readable medium of claim 4 further comprising instructions for dividing the photomask pattern into blocks, wherein approximating an electromagnetic field in the vicinity of the photomask pattern using the 2-dimensional model of the photomask pattern further comprises applying the model separately to each block.

7. The computer readable medium of claim 6, further comprising instructions for assembling the modified blocks.
